(19) United States
(12) Patent Application Publication
(10) Pub. No.: US 2026/0229456 A1
(43) Pub. Date: Aug. 6, 2026

(54) System and Method for Atomic Layer Etching Using Capacitively Coupled Plasma with Enhanced Synergy

(71) Applicant: Yang Pan, SINGAPORE (SG)

(72) Inventor: Yang Pan, SINGAPORE (SG)

(73) Assignee: Inspiring Atoms Pte Ltd, SINGAPORE (SG)

(21) Appl. No.: 19/046,554

(22) Filed: Feb. 6, 2025

(51) Int. Cl. H01J 37/32

(52) U.S. Cl. CPC H01J 37/32091; H01J 37/32128; H01J 37/32146; H01J 37/32568; H01J 2237/334

(57) ABSTRACT

Disclosed herein are systems and methods for an atomic layer etching (ALE) process that includes a surface modification step and a sputtering step. An improved capacitively coupled plasma (CCP) source with sidewall coils is utilized to enhance plasma density and reduce ion bombardment during the surface modification step. During the sputtering step, the CCP process chamber operates with the sidewall coils deactivated.

### FIELD OF THE INVENTION

The present invention relates to atomic layer etching (ALE) processes and systems. More specifically, the invention pertains to an ALE process system utilizing a capacitively coupled plasma (CCP) source with supplemental sidewall coils to reduce ion bombardment during surface modification step.

### BACKGROUND OF THE INVENTION

Anisotropic ALE is a plasma-based etching technique that includes a surface modification step and a sputtering step. The distinct chemistry, speciation, and plasma energy composition involved in the surface modification and sputtering steps enhance the process by enabling more controlled ion, electron, and neutral species fluxes, thereby widening the process window. This separation facilitates self-limiting reactions, crucial for maintaining the ideality of the etching process-characterized by uniformity, smoothness, and selectivity. Karanik et al., in “Predicting synergy in atomic layer etching” (J. Vac. Sci. Technol. A35, pages 05C302 1-7, 2017), defined ALE synergy as:

$${ALE}_{synergy} S ( \% ) = \frac{EPC - ( α + β )}{EPC} \times 100 \% , \qquad [ 1 ]$$

where EPC is “etch per cycle,” representing the total thickness of material removed in one cycle, typically averaged over many cycles. The values of “α” and “β” are (undesirable) contributions from the surface modification step and the sputtering step, respectively. Ideally, synergy will approach 100% with no etching from either step alone. In practice, RIE in the surface modification step is nonzero because of the presence of ions in the plasma, which generates neutrals to modify the surface. In the sputtering step, physical sputtering of the underlying unmodified layer is also nonzero.

It is desirable for the plasma in the surface modification step of the ALE process to be free from ion bombardment. However, the unintended introduction of RIE components during this step presents a persistent challenge. This issue stems from the difficulty in completely preventing ion bombardment of the substrate surface, compromising the ideality of the ALE processes. Modern ALE methodologies struggle to effectively eliminate these RIE components, leading to suboptimal etching outcomes, particularly as device geometries become more complex and smaller in scale. The presence of RIE components in ALE processes can result in non-uniform layer removal and undesirable etching profiles, which are especially problematic in advanced device manufacturing where even minor deviations can significantly impact device performance and yield.

Most ALE processes are based on inductively coupled plasma (ICP) source. Capacitively coupled plasma (CCP) based ALE faces a fundamental challenge: high plasma density, necessary for rapid surface modification, inherently leads to high ion bombardment. While a high density of radicals is required to achieve fast and uniform modification, the associated ion energy can cause unintended RIE, undermining the self-limiting nature of ALE. Since plasma density and ion energy are intrinsically linked in CCP systems, reducing ion bombardment without sacrificing radical concentration is difficult. Adjusting process parameters such as RF power or pressure affects both plasma density and sheath potential, making it nearly impossible to maintain the required radical flux while minimizing ion impact.

To overcome this limitation, a supplementary plasma source, such as sidewall coils, can be introduced to provide additional radical generation independent of ion energy. By utilizing an inductively coupled plasma (ICP) component alongside CCP, radical production can be enhanced without significantly increasing ion energy. This hybrid approach enables better control over plasma properties, allowing for effective decoupling of radical production and ion bombardment, thereby improving the fidelity of the ALE process.

### SUMMARY

In some embodiments, the present invention provides an atomic layer etching (ALE) system incorporating a capacitively coupled plasma (CCP) source with supplemental sidewall coils to generate high density radicals while minimizing ion bombardment during the surface modification step. The key feature of the invention is the integration of the sidewall coils, which generates an additional plasma source independent of the ion energy associated with a CCP process system.

In ALE processes, high plasma density is required for rapid surface modification; however, in the CCP process system, this high density is inherently coupled with high ion bombardment, which can lead to unintended RIE and reduce synergy. The sidewall coils address this issue by providing enhanced radical generation without significantly increasing ion energy, thereby decoupling radical flux from ion bombardment. This enables precise surface modification while preserving the self-limiting nature of ALE.

In some implementations, the ALE system utilizes the sidewall coils alone to generate radicals during the surface modification step. In other implementations, the sidewall coils are combined with a high-frequency RF power generator coupled to the anode to further enhance plasma density while minimizing ion bombardment. Additionally, the sputtering step may employ a tailored waveform generator in conjunction with a low-frequency RF power applied to the anode to optimize ion energy distribution and improve directionality of the ions during the sputtering step.

Pulsing schemes may also be incorporated to precisely control plasma characteristics. In some implementations, the RF power applied to the anode has a shorter pulse duration than the RF power supplied to the sidewall coil to further mitigate ion bombardment while maintaining efficient radical production. These configurations provide enhanced process flexibility, ensuring better control over etching selectivity, uniformity, and precision.

By utilizing a hybrid plasma configuration combining CCP with an inductively coupled plasma (ICP) component from the sidewall coils, along with various implementations in RF power delivery, the invention achieves improved ALE synergy while leveraging small plasma volume of a CCP reactor for faster gas exchanging. The system controller coordinates RF power supply, pulsing schemes, and waveform tailoring to optimize ALE performance, making the approach suitable for advanced semiconductor fabrication processes requiring damage-free, atomic-scale precision.

### BRIEF DESCRIPTIONS OF THE DRAWINGS

The clarity of the embodiments is enhanced by referring to the following description in conjunction with the accompanying drawings:

FIG. 1: Illustrates an exemplary ALE process system using a CCP source with added sidewall coils to enhance radical generation and reduce ion bombardment during surface modification.

FIG. 2: Presents a flowchart of an ALE process utilizing the CCP source with integrated sidewall coils, detailing the sequential steps of surface modification and sputtering.

### DETAILED DESCRIPTIONS

To foster a comprehensive understanding, this description elaborates on specific implementations of the current invention. While specific details are provided for elucidation, adjustments and variations that align with the following claims are deemed acceptable. Some established procedures and components are selectively detailed to underscore the unique facets of the invention.

### Terms Used

Atomic Layer Etching (ALE): A plasma-based etching process that removes material layer-by-layer through alternating surface modification and sputtering steps, enabling precise control at the atomic scale.
Process Chamber: A vacuum-sealed enclosure where the ALE process is conducted, designed to maintain controlled plasma and gas flow conditions.
Capacitively Coupled Plasma (CCP) Source: A plasma generation method where an electric field between an anode (chuck) and a cathode (grounded showerhead) sustains the plasma, typically used in semiconductor processing.
Chuck: A substrate holder serving as the anode in the CCP system, which may be an electrostatic chuck (ESC) or a vacuum chuck, securing the wafer during processing.
Grounded Showerhead: A component that acts as the cathode in the CCP system, distributing process gases into the process chamber.
Sidewall Coils: One or more inductively coupled RF coils that generate plasma independently of ion energy, helping to produce radicals for surface modification with minimized ion bombardment.
RF Power Generator: Supplies radio frequency (RF) power at different frequencies to sustain and control plasma, where higher frequencies enhance plasma density and lower frequencies enhance ion energy.
Resonator: An impedance-matching component that optimizes power transfer between RF generators and the process chamber, ensuring stable plasma operation across different process steps.
Tailored Waveform Generator: A device that modifies the RF power waveform applied to the chuck, reducing the ion energy distribution to optimize sputtering step.
Surface Modification Step: The first half of an ALE cycle where radicals in the plasma chemically react with the substrate, forming a modified layer that can be selectively removed in the next step.
Sputtering Step: The second half of an ALE cycle where energetic ions physically remove the modified layer, completing one full etching cycle with controlled material removal.
System Controller: A computing system with software modules that regulate process parameters, RF power application, gas flow rates, and pulsing schemes to maintain precise ALE operation.
Pulsing Scheme: A method of controlling RF power application through timed pulses, optimizing plasma ignition, ion energy, and radical generation for different ALE process steps.
Bias Voltage: An electrical potential applied to the chuck to control the energy and directionality of ions in the plasma, critical for achieving anisotropic etching in high aspect ratio structures.
Process Gas: Reactive gases such as chlorine, used for surface modification, and inert gases such as argon, used for sputtering, playing distinct roles in each ALE cycle.

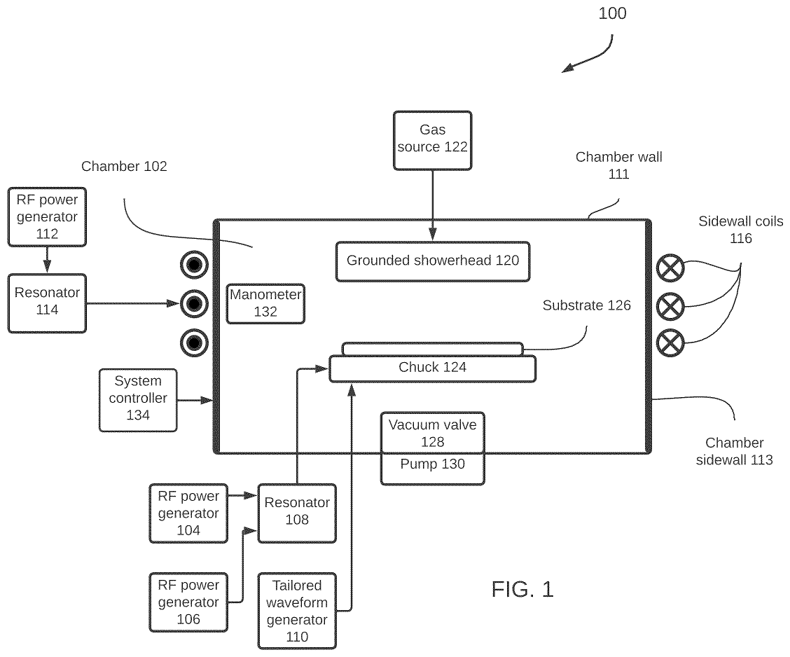

FIG. 1 illustrates an exemplary atomic layer etching (ALE) process system, denoted as 100. The process system 100 includes a process chamber 102, which is configured to conduct a plasma-based process within a vacuum environment. The process chamber 102 is enclosed by a chamber wall 111. The chamber wall includes a sidewall 113, which are constructed from dielectric materials such as quartz or ceramic. The process chamber 102 further includes a capacitively coupled plasma (CCP) source, which comprises a chuck 124 as its anode and a grounded showerhead 120 as its cathode. The chuck 124 may be an electrostatic chuck (ESC) or a vacuum chuck, depending on the application. The grounded showerhead 120 may be constructed from conductive materials such as silicon. The grounded showerhead 120 receives process gases from a gas source 122 and distributes the received gases into the process chamber 102. The gas source 122 includes a gasbox, various valves, and mass flow controllers (MFCs). The chuck 124 supports a substrate 126, which is typically a silicon wafer.

Process gases, including reaction by-products, are evacuated from the process chamber 102 by a pump 130. A vacuum valve 128, located upstream of the pump, regulates the gas removal rate.

The evacuated gases are directed to an exhaust via an exhaust line (not shown in FIG. 1). The chamber pressure is controlled by balancing the injection and removal rates of gases, with a proportional-integral-derivative (PID) control loop adjusting the pressure based on readings from a manometer 132.

The chuck 124, serving as the anode, receives RF power from one or more RF power generators. FIG. 1 depicts an example with two RF power generators, 104 and 106, which may be operated at different frequencies. The RF power generator 104 may operate at 60 MHz, while the RF power generator 106 may operate at 400 kHz. The higher RF frequency is used to increase plasma density, while the lower frequency is utilized to increase ion energy. The RF power generators are coupled to the chuck 124 via a resonator 108, which is used to match the impedance of the RF power generators to the impedance of the CCP. It should be noted that the plasma may exhibit different states during an ALE process. For example, the surface modification step and the sputtering step may exhibit different plasma impedances. The resonator 108 is configured to match the impedance of the RF power generators by taking such impedance variations into consideration.

A tailored waveform generator 110 may be employed to improve ion energy distribution during the sputtering step. The tailored waveform generator 110 is typically used in conjunction with one of the RF power generators.

The process system 100 further includes one or more sidewall coils, denoted as 116. An RF power generator 112 supplies RF power at a predetermined frequency, such as 13.56 MHz, to the sidewall coils 116 via a resonator 114. In one implementation, a single coil with single or multiple turns is used. In another implementation, multiple separated coils are used, each driven by a separate RF power generator operating at different power levels or frequencies. One of the key challenges associated with using a CCP source for ALE lies in the difficulty of eliminating ion bombardment during the surface modification step, which requires a high concentration of radicals to modify the substrate surface with a short step time of less than 200 milliseconds. It is well known that higher plasma density, and hence radical concentration, is associated with high ion energy for the CCP source. This makes it difficult to achieve an ALE process with high synergy using a CCP source due to excessive ion bombardment during the surface modification step.

The use of sidewall coils 116 mitigates this issue by incorporating an additional plasma source that is independent of ion energy.

In some implementations, the duration of the RF power generator 104 or 106 is shorter than the duration of the RF power generator 112, during the surface modification step, to reduce ion bombardment.

In other implementations, the RF power is pulsed according to predetermined pulsing schemes. The duration of the pulses from the RF generator 104 or 106 is shorter than the duration of the pulses from the RF power generator 112.

In some aspects, the starting time of the pulses from the RF power generator 112 may be managed to have a delay from the pulses from the RF power generator 104 or 106 to effectively ignite plasma, particularly when electronegative process gases such as chlorine are used during the surface modification step.

An ALE process operates cyclically, typically involving two process gases delivered in two distinct steps: a surface modification step and a sputtering step, often referred to as two half-cycles that complete one ALE cycle. The grounded showerhead 120 may have two distinct gas distribution patterns consisting of gas channels and injection holes for the first and the second process gases, respectively.

The operations of the process system 100 are coordinated by a system controller 134, which comprises a computer and various software modules.

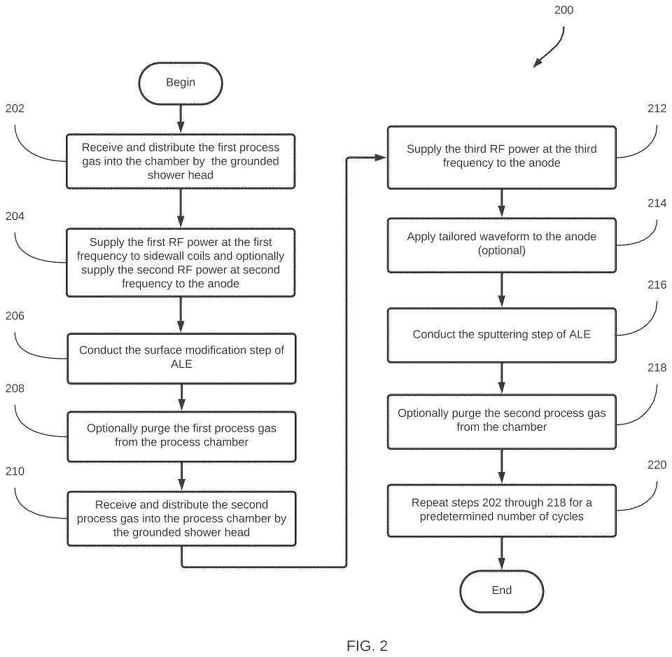

FIG. 2 illustrates a flowchart for an ALE process using the process system 100. Process 200 starts with step 202, where the system controller 134 instructs the grounded showerhead 120 to receive the first process gas, such as chlorine, from the gas source 122. Subsequently, the first process gas is distributed into the process chamber 102 by the grounded showerhead 120. In step 204, the sidewall coils 116 receive a first RF power at a first frequency from RF power generator 112 via resonator 114. The first frequency may be 13.56 MHz, with a power level ranging from 50 watts to 5000 watts. During the step, a second RF power at a second frequency may also be supplied to the anode from the RF power generator 104. The second frequency may be 60 MHz or 27 MHz. The power level may range from 50 to 500 watts.

In step 206, the surface modification of the substrate 126 is performed by radicals in the plasma, ensuring the formation of a modified layer with self-limiting characteristics. The exposure duration is controlled to balance process performance and productivity.

In step 208, the first process gas may be optionally purged using a gas such as nitrogen.

In step 210, the grounded showerhead 120 receives and distributes a second process gas, such as argon, into the process chamber 102. In step 212, the anode receives a third RF power at a third frequency from the RF power generator 106 to the chuck 124. The sidewall coils 116 are deactivated. The third RF frequency is selected to optimize ion energy for the sputtering step.

The third RF frequency may be selected from a group comprising: 2 MHz, 1 MHz, 400 kHz, and 100 kHz.

In step 214, a tailored waveform generator 110 may be optionally applied to improve ion energy distribution.

In step 216, the sputtering step is performed, where ions in the plasma remove the modified layer. The bias voltage may range from approximately 50 to 5000 volts, and the RF power and tailored waveform can be pulsed according to a predetermined pulsing scheme.

In step 218, the second process gas may be optionally purged using nitrogen or another inert gas.

In step 220, steps 202 to 218 are repeated for a predetermined number of cycles to complete the ALE process. The number of cycles is adjusted based on the required etch depth and material removal rate. The system controller 134 dynamically manages process parameters, including RF power levels, pulsing schemes, and gas flow rates, ensuring consistent etch performance and process uniformity.

By leveraging independent plasma sources and precise control over plasma characteristics, the process system 100 with the CCP source enhances ALE to achieve higher synergy by incorporating an ICP source positioned along the sidewall of the process chamber.

1. A process system for conducting an atomic layer etching (ALE) process, comprising:
a process chamber configured to operate under vacuum conditions, comprising a sidewall constructed from dielectric materials;
a chuck located within the process chamber, configured to support a substrate during an ALE process;
a showerhead configured to receive and distribute process gases into the process chamber, wherein the showerhead is grounded;
one or more RF power generators coupled to the chuck to supply power to a capacitively coupled plasma (CCP) source, which uses the chuck as the anode and the grounded showerhead as the cathode;
one or more sidewall coils positioned along an external surface of the sidewall of the process chamber; and
a system controller configured to operate the process chamber in a surface modification step and a sputtering step, wherein the sidewall coils are activated during the surface modification step and deactivated during the sputtering step.

2. The system of claim 1, wherein the system further includes a tailored waveform generator that is activated during the sputtering step.

3. The system of claim 2, wherein the tailored waveform generator together with one of the RF power generators coupled to the chuck provides a bias voltage ranging from 50 to 5000 volts to accelerate ions within the process chamber.

4. The system of claim 1, wherein the sidewall coils are coupled to one or more RF power generators.

5. The system of claim 4, wherein the RF power generators operate at one of or more frequencies selected from the following group: 13.56 MHz, 2 MHz, 1 MHz, 400 kHz, and 100 kHz.

6. The system of claim 1, wherein the RF power generators coupled to the chuck operate at one or more frequencies selected from the following frequencies from the following group: 100 MHz, 60 MHz, 27 MHz, 13.56 MHz, 2 M Hz, 1 MHz, 400 kHz, and 100 kHz.

7. The system of claim 1, wherein the RF powers supplied to the chuck operates at different frequencies for the surface modification step and the sputtering step, wherein the frequency used for the sputtering step is lower than the frequency used for the surface modification step.

8. The system of claim 1, wherein at least one RF power source is pulsed.

9. The system of claim 8, wherein the pulsed RF power supplied to the chuck is pulsed with a shorter duration than the RF power supplied to the sidewall coils.

10. The system of claim 1, wherein at least one of the RF power generators coupled to the chuck is deactivated during the surface modification step.

11. The system of claim 1, wherein the grounded showerhead is configured with distinct gas distribution patterns for the first and the second process gases.

12. The system of claim 1, wherein the dielectric materials include quartz or ceramic.

13. The system of claim 1, wherein the process chamber has a plasma volume less than 5 liters.

14. A method for processing a substrate using an ALE process, comprising:
a. providing a process chamber under vacuum conditions configured to conduct an ALE process, wherein the process chamber includes a CCP source using a chuck as an anode and a grounded showerhead as a cathode, wherein one or more sidewall coils positioned along a dielectric sidewall provide additional RF power during the surface modification step;
b. receiving and distributing a first process gas into the process chamber via the grounded showerhead;
c. supplying a first RF power at a first frequency to the sidewall coils and optionally supplying a second RF power at second frequency to the anode;
d. conducting the surface modification step of the ALE process;
e. optionally purging the first process gas from the process chamber;
f. receiving and distributing a second process gas into the process chamber via the grounded showerhead;
g. supplying a third RF power at a third frequency to the anode;
h. optionally applying a tailored waveform generator to the anode during the sputtering step;
i. conducting the sputtering step of the ALE process;
j. optionally purging the second process gas from the process chamber; and
k. repeating steps (b) through (j) for a predetermined number of cycles to complete the ALE process.

15. The method of claim 14, further including deactivating the RF power supplied to the sidewall coils after completing the surface modification step.

16. The method of claim 14, wherein the first RF power includes multiple frequencies.

17. The method of claim 16, wherein the first RF power is supplied to multiple sidewall coils, with each coil receiving the RF power at a distinct frequency.

18. The method of claim 16, wherein the system controller controls the RF power according to predetermined pulsing schemes.

19. The method of claim 18, wherein, during the surface modification step, the pulsed RF power supplied to the sidewall coils and the pulsed RF power supplied to the anode are synchronized.

20. The method of claim 18, wherein, during the surface modification step, the system controller operates the pulsed RF power supplied to the anode with shorter duration than the pulsed RF power supplied to the sidewall coils.
